(19) United States
(12) Patent Application Publication
(10) Pub. No.: US 2026/0011640 A1
(43) Pub. Date: Jan. 8, 2026

(54) SEMICONDUCTOR DEVICE

(71) Applicant: SAMSUNG ELECTRONICS CO., LTD., Suwon-si (KR)

(72) Inventors: Junhoi KIM, Suwon-si (KR); Subin KIM, Suwon-si (KR); Jiwon OH, Suwon-si (KR); Jae Hyun KANG, Suwon-si (KR); Jinho PARK, Suwon-si (KR); Joongwon JEON, Suwon-si (KR)

(73) Assignee: SAMSUNG ELECTRONICS CO., LTD., Suwon-si (KR)

(21) Appl. No.: 19/094,196

(22) Filed: Mar. 28, 2025

(30) Foreign Application Priority Data
Jul. 8, 2024 (KR) 10-2024-0089644

(51) Int. Cl. H01L 23/528; H01L 23/522; H01L 23/532; H10D 84/83

(52) U.S. Cl. CPC H01L 23/5283; H01L 23/5226; H10D 84/83; H01L 23/53214; H01L 23/53228; H01L 23/53257

(57) ABSTRACT

A semiconductor device includes a substrate, a source/drain pattern on the substrate, a gate structure on the substrate, an active contact connected to the source/drain pattern, a gate contact connected to the gate structure, and a wiring structure on the active contact, where the wiring structure includes a bridge wiring layer and a plurality of conductive wiring layers, the bridge wiring layer includes an active via connected to the active contact and a gate via connected to the gate contact, and each conductive wiring layer of the plurality of conductive wiring layers includes an active via connected to the active contact, a gate via connected to the gate contact, an active line on the active via of the respective conductive wiring layer, and a gate line on the gate via of the respective conductive wiring layer.

### CROSS-REFERENCE TO RELATED APPLICATION

This application is based on and claims priority under 35 U.S.C § 119 to Korean Patent Application No. 10-2024-0089644, filed on Jul. 8, 2024, in the Korean Intellectual Property Office, the disclosure of which is incorporated by reference herein in its entirety.

### BACKGROUND

The present disclosure relates to a semiconductor device, and more particularly, to a semiconductor device including a transistor.

A semiconductor device may include an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device which may have increased reliability and improved electrical properties.

Additional aspects will be set forth in part in the description which follows and, in part, will be apparent from the description, or may be learned by practice of the presented embodiments.

According to an aspect of an example embodiment, a semiconductor device may include a substrate, a source/drain pattern on the substrate, a gate structure on the substrate, an active contact connected to the source/drain pattern, a gate contact connected to the gate structure, and a wiring structure on the active contact, where the wiring structure includes a bridge wiring layer and a plurality of conductive wiring layers, the bridge wiring layer includes an active via connected to the active contact and a gate via connected to the gate contact, each conductive wiring layer of the plurality of conductive wiring layers includes an active via connected to the active contact, a gate via connected to the gate contact, an active line on the active via of the respective conductive wiring layer, and a gate line on the gate via of the respective conductive wiring layer, and the bridge wiring layer includes a connection line connected to the active via of the bridge wiring layer and the gate via of the bridge wiring layer.

According to an aspect of an example embodiment, a semiconductor device may include a substrate, a source/drain pattern on the substrate, a gate structure on the substrate, an active contact connected to the source/drain pattern, a gate contact connected to the gate structure, and a wiring structure on the active contact, where the wiring structure includes a plurality of wiring layers that are vertically stacked, the plurality of wiring layers include a first conductive wiring layer contacting the active contact and the gate contact and a bridge wiring layer, the bridge wiring layer includes an active via connected to the active contact and a gate via connected to the gate contact, the first conductive wiring layer includes an active via connected to the active contact, a gate via connected to the gate contact, an active line contacting the active via of the first conductive wiring layer, and a gate line spaced apart from the active line and on the gate via of the first conductive wiring layer, and the bridge wiring layer includes a connection line contacting the active via of the bridge wiring layer and the gate via of the bridge wiring layer.

According to an aspect of an example embodiment, a semiconductor device may include a substrate including an active pattern, a channel pattern on the active pattern, the channel pattern including a plurality of semiconductor patterns that are vertically stacked and spaced apart from each other, a gate electrode on the plurality of semiconductor patterns, a source/drain pattern on the active pattern, a gate dielectric layer between the gate electrode and semiconductor patterns that are adjacent to each other, a gate contact connected to the gate electrode, an active contact connected to the source/drain pattern, and a wiring structure on the active contact, where the wiring structure includes a bridge wiring layer and a plurality of conductive wiring layers, the bridge wiring layer includes an active via connected to the active contact and a gate via connected to the gate contact, each conductive wiring layer of the plurality of conductive wiring layers includes an active via connected to the active contact, a gate via connected to the gate contact, an active line on the active via of the respective conductive wiring layer, and a gate line on the gate via of the respective conductive wiring layer, and the bridge wiring layer includes a connection line connected to the active via of the bridge wiring layer and the gate via of the bridge wiring layer.

### BRIEF DESCRIPTION OF THE DRAWINGS

The above and other aspects, features, and advantages of certain example embodiments of the present disclosure will be more apparent from the following description taken in conjunction with the accompanying drawings, in which:

FIG. 1 is a plan view illustrating a semiconductor device according to one or more embodiments.

FIGS. 2 and 3 are cross-sectional views of a semiconductor device taken along line A-A′ of FIG. 1 according to one or more embodiments.

FIG. 4A is a plan view illustrating a semiconductor device according to one or more embodiments.

FIG. 4B is a cross-sectional view of a semiconductor device taken along line A-A′ of FIG. 4A according to one or more embodiments.

FIGS. 5A to 5H are cross-sectional views illustrating a method of fabricating a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

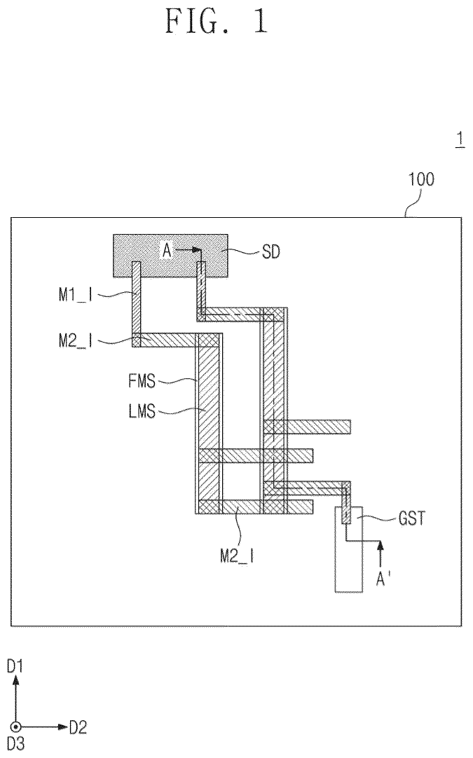

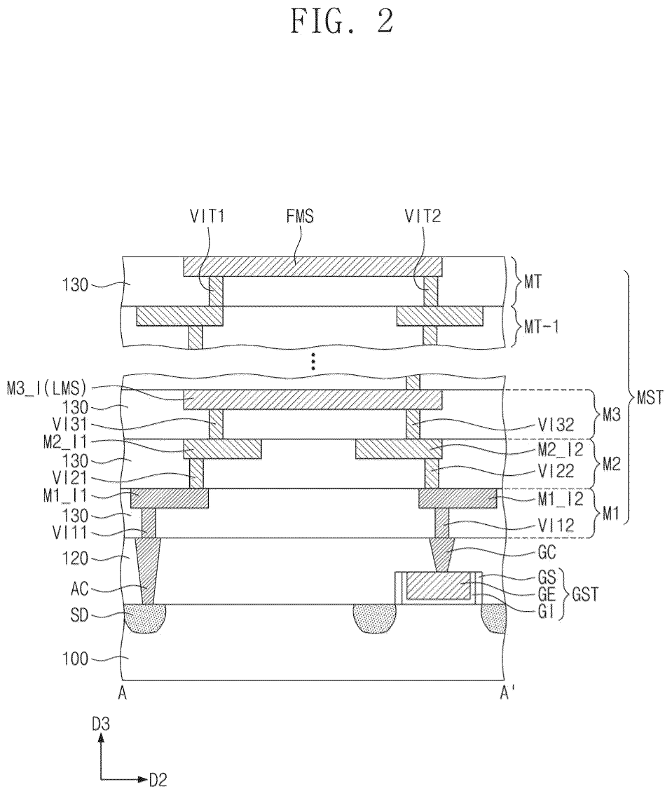

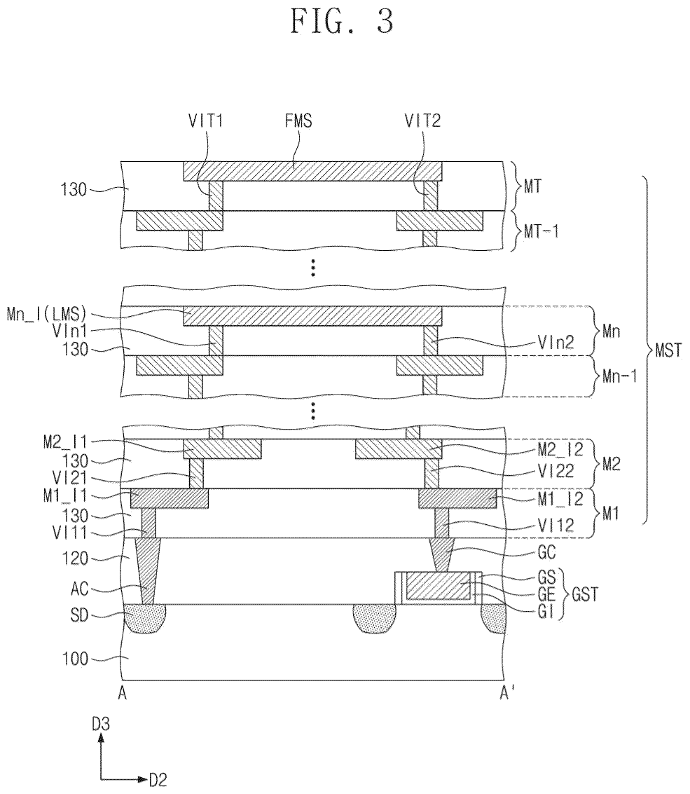

FIG. 1 is a plan view illustrating a semiconductor device according one or more embodiments. FIGS. 2 and 3 are cross-sectional views of a semiconductor device taken along line A-A′ of FIG. 1, according to one or more embodiments.

Referring to FIGS. 1 to 3, a semiconductor device 1 may include a substrate 100 which extends in a first direction D1 and a second direction D2. A gate structure GST may be disposed on the substrate 100. A source/drain pattern SD may be disposed on an upper side of the substrate 100. A top surface of the gate structure GST may be located at a level higher than that of a top surface of the source/drain pattern SD.

The gate structure GST may include a gate dielectric layer GI on the substrate 100, a gate electrode GE on the gate dielectric layer GI, and a gate spacer GS on opposite sidewalls of the gate electrode GE. The gate dielectric layer GI may surround lateral and bottom surfaces of the gate electrode GE. The gate electrode GE may include a conductive material. The gate electrode GE may contact the gate dielectric layer GI. The gate dielectric layer GI may contact the gate spacer GS.

The substrate 100 may be provided thereon with a first interlayer dielectric layer 120, an active contact AC, and a gate contact GC. The first interlayer dielectric layer 120 may surround lateral surfaces of the active contact AC and the gate contact GC. The first interlayer dielectric layer 120 may include a dielectric material. The first interlayer dielectric layer 120 may include, for example, a silicon oxide layer.

The active contact AC may be electrically connected to the source/drain pattern SD. The active contact AC may contact the source/drain pattern SD. The gate contact GC may be electrically connected to the gate structure GST. The gate contact GC may contact the gate electrode GE. The active contact AC and the gate contact GC may include a conductive material. A height of the active contact AC in a third direction D3 perpendicular to the substrate 100 may be greater than a height in the third direction D3 of the gate contact GC.

A wiring structure MST may be disposed on the active contact AC and the gate contact GC. The wiring structure MST may include a plurality of wiring layers M1, M2, . . . , Mn, . . . , and MT that are vertically stacked on the substrate 100. The plurality of wiring layers M1, M2, . . . , Mn, . . . , and MT may include a second interlayer dielectric layer 130. The second interlayer dielectric layer 130 may include a dielectric material.

The plurality of wiring layers M1 to MT may include a bridge wiring layer Mn and a plurality of conductive wiring layers M1, M2, . . . , Mn−1, Mn+1, . . . , and MT. The bridge wiring layer Mn may refer to a wiring layer having a connection line LMS which will be described below. The wiring structure MST may include a first conductive wiring layer M1 contacting the active contact AC and the gate contact GC. A second conductive wiring layer M2 may be disposed on the first conductive wiring layer M1. The bridge wiring layer Mn may be disposed on the first conductive wiring layer M1.

A third conductive wiring layer M3 on the second conductive wiring layer M2 may have a connection line LMS, and in this case, the third conductive wiring layer M3 may be a bridge wiring layer. For example, the third conductive wiring layer M3 may be a bridge wiring layer, and an active via VI31 and a gate via VI32 of the bridge wiring layer M3 may be connected through a connection line M3_I of the bridge wiring layer M3.

The bridge wiring layer Mn and the conductive wiring layers M1, M2, . . . , Mn−1, Mn+1, . . . , and MT may include corresponding active vias VI11, VI21, etc. that are connected to the active contact AC, and may also include corresponding gate vias VI12, VI22, etc. that are connected to the gate contact GC. The second interlayer dielectric layer 130 may surround lateral surfaces of the active vias VI11, VI21, etc., and may also surround lateral surfaces of the gate vias VI12, VI22, etc.

The conductive wiring layers M1, M2, . . . , Mn−1, Mn+1, . . . , and MT may include active lines M1_I1, M2_I1, etc. on the active vias VI11, VI21, etc., and may also include gate lines M1_I2, M2_I2, etc. on the gate vias VI12, VI22, etc. The active lines M1_I1, M2_I1, etc. and the gate lines M1_I2, M2_I2, etc. of the conductive wiring layers M1, M2, . . . , Mn−1, Mn+1, . . . , and MT may be spaced apart from each other.

The bridge wiring layer Mn may include a connection line LMS connected to an active via VIn1 and a gate via VIn2 of the bride wiring layer Mn. A width of the connection line LMS may be greater than that of each of the active lines M1_I1, M2_I2, etc. or greater than that of each of the gate lines M1_I2, M2_I2, etc. The connection line LMS may overlap the active via VIn1 and the gate via VIn2 of the bridge wiring layer Mn. The connection line LMS may include a conductive material. The connection line LMS may include aluminum, copper, tungsten, molybdenum, or cobalt. The connection line LMS may vertically overlap at least two vias.

The first conductive wiring layer M1 may include a first active via VI11 connected to the active contact AC and a first gate via VI12 connected to the gate contact GC. The second conductive wiring layer M2 may include a second active via VI21 connected to the active contact AC and a second gate via VI22 connected to the gate contact GC. Other conductive wiring layers may be the same as that described above.

The bridge wiring layer Mn and the plurality of conductive wiring layers M1, M2, . . . , Mn−1, Mn+1, . . . , and MT may be vertically stacked. At least two conductive wiring layers M1, M2, . . . , Mn−1, Mn+1, . . . , and MT may be disposed beneath the bridge wiring layer Mn.

A conductive wiring layer at top of the wiring structure MST may be an uppermost wiring layer MT. An active via VIT1 and a gate via VIT2 of the uppermost wiring layer MT may be connected to an uppermost line FMS. The bridge wiring layer Mn may be positioned between the uppermost wiring layer MT and the first conductive wiring layer M1. One or more conductive wiring layers M1, M2, . . . , Mn−1, and Mn+1 may be disposed between the uppermost wiring layer MT and the bridge wiring layer Mn.

The uppermost line FMS may contact the active via VIT1 and the gate via VIT2 of the uppermost wiring layer MT. A width of the uppermost line FMS may be greater than that of each of the active lines M1_I1, M2_I2, etc. of the conductive wiring layers M1, M2, . . . , Mn−1, Mn+1, . . . , and MT, or greater than that of each of the gate lines M1_I2, M2_I2, etc. of the conductive wiring layers M1, M2, . . . , Mn−1, Mn+1, . . . , and MT.

The wiring structure MST according to one or more embodiments may have the bridge wiring layer Mn, and the bridge wiring layer Mn may have the connection line LMS. The connection line LMS may be disposed between the uppermost wiring layer MT and the first conductive wiring layer M1 or a conductive wiring layer positioned at a bottom location. Therefore, an induced charge generated during the fabrication of the semiconductor device may move through the connection line LMS to the source/drain pattern SD. Accordingly, an induced charge that moves to the gate structure GST may be reduced.

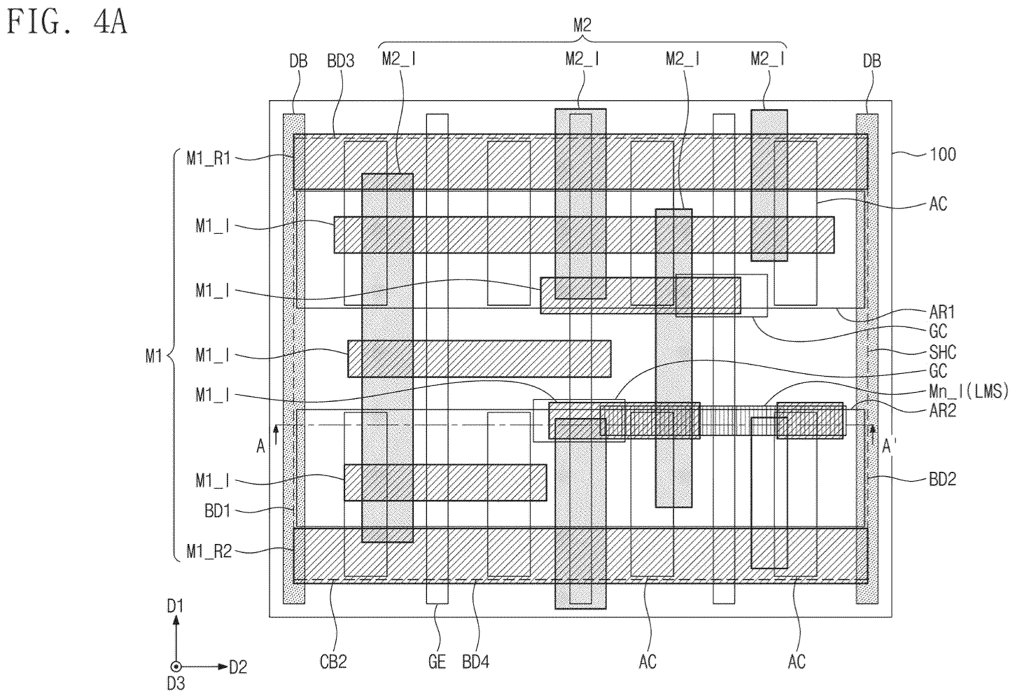

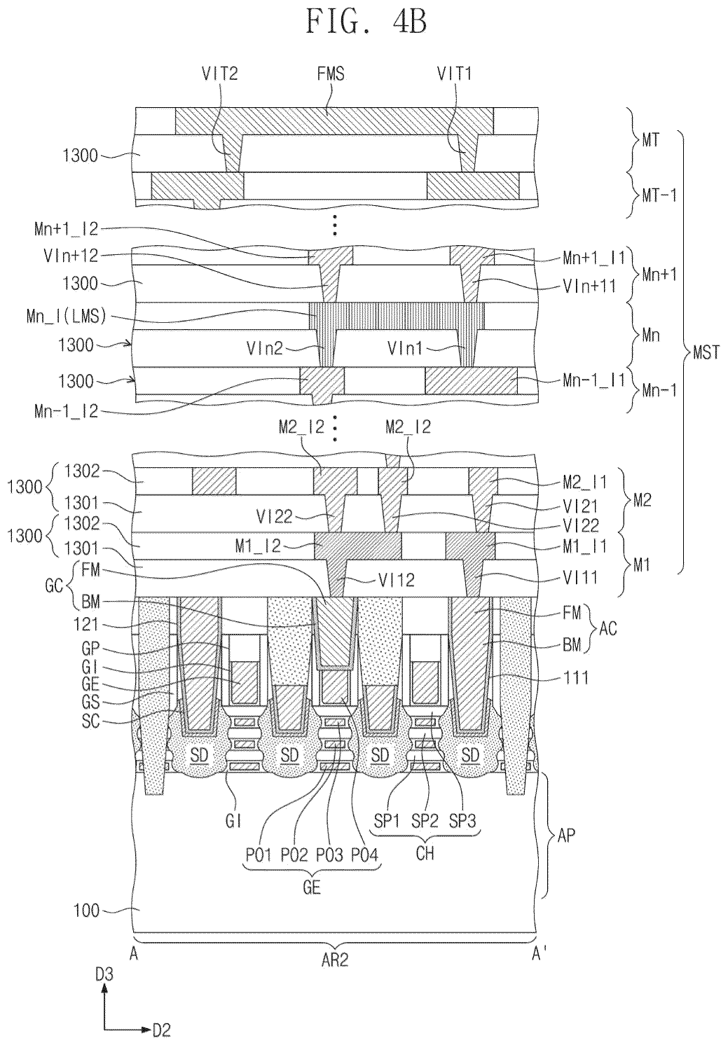

FIG. 4A is a plan view illustrating a semiconductor device according to one or more embodiments. FIG. 4B is a cross-sectional view of a semiconductor device taken along line A-A′ of FIG. 4A according to one or more embodiments.

Referring to FIGS. 4A and 4B, a single height cell SHC may be provided on a substrate 100. The single height cell SHC may be provided thereon with logic transistors included in a logic circuit. The substrate 100 may be a compound semiconductor substrate or a semiconductor substrate including silicon, germanium, or silicon-germanium. For example, the substrate 100 may be a silicon substrate.

The substrate 100 may include an active pattern AP. The substrate 100 may include a first active region AR1 and a second active region AR2. Each of the first and second active regions AR1 and AR2 may extend in a second direction D2. In one or more embodiments, the first active region AR1 may be an n-type metal-oxide-semiconductor (MOS) field effect transistor (FET) (MOSFET) (NMOSFET) region, and the second active region AR2 may be a p-type MOSFET (PMOSFET) region.

A channel pattern CH may be provided on the active pattern AP. The channel pattern CH may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in a vertical direction (or a third direction D3).

Each of the first, second, and third semiconductor patterns SP1, SP2, and SP3 may include silicon (Si), germanium (Ge), or silicon-germanium (SiGe). For example, each of the first, second, and third semiconductor patterns SP1, SP2, and SP3 may include crystalline silicon, for example, monocrystalline silicon. In one or more embodiments, the first, second, and third semiconductor patterns SP1, SP2, and SP3 may be stacked nano-sheets.

A plurality of source/drain patterns SD may be provided on the active pattern AP. A plurality of recesses may be formed on an upper portion of the active pattern AP. The source/drain patterns SD may be correspondingly provided in the recesses. The source/drain patterns SD may be impurity regions having a first conductivity type (e.g., n-type) or a second conductivity type (e.g., p-type). The channel pattern CH may be interposed between a pair of source/drain patterns SD. For example, the first, second, and third semiconductor patterns SP1, SP2, and SP3 may connect the pair of source/drain patterns SD to each other.

The source/drain patterns SD may be epitaxial patterns formed by a selective epitaxial growth (SEG) process. For example, a top surface of each of the source/drain patterns SD may be higher than a top surface of the third semiconductor pattern SP3. In one or more embodiments, the top surface of at least one of the source/drain patterns SD may be located at substantially the same level as that of the top surface of the third semiconductor pattern SP3.

In one or more embodiments, the source/drain pattern SD may include the same semiconductor element (e.g., Si) as that of the substrate 100. In one or more embodiments, the source/drain pattern SD may include a semiconductor element (e.g., SiGe) whose lattice constant is greater than that of a semiconductor element included in the substrate 100. In this case, a pair of source/drain patterns SD may provide a compressive stress to the channel pattern CH therebetween.

In one or more embodiments, a sidewall of the source/drain pattern SD may have a rugged embossing shape. For example, the sidewall of the source/drain pattern SD may have a wavy profile. The sidewall of the source/drain pattern SD may protrude toward first, second, and third inner electrodes PO1, PO2, and PO3 of a gate electrode GE which will be described below.

Gate electrodes GE may be provided on the channel patterns CH. Each of the gate electrodes GE may extend in a first direction D1, while extending across the channel patterns CH. Each of the gate electrodes GE may be vertically above the channel patterns CH. The gate electrodes GE may be arranged at a first pitch in the second direction D2. The gate electrodes GE may extend in the first direction D1, and may be arranged in the second direction D2.

The gate electrode GE may include a first inner electrode PO1 interposed between the active pattern AP and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

The gate electrode GE may surround a top surface, a bottom surface, and opposite sidewalls of each of the first, second, and third semiconductor patterns SP1, SP2, and SP3. For example, a transistor according to one or more embodiments may be a three-dimensional FET (e.g., multi-bridge channel FET (MBCFET), gate-all-around FET (GAAFET)) in which the gate electrode GE three-dimensionally surrounds a channel pattern CH.

The gate electrode GE may include a first metal pattern and a second metal pattern on the first metal pattern. The first metal pattern may be provided on the gate dielectric layer GI and may be adjacent to the first, second, and third semiconductor patterns SP1, SP2, and SP3. The first metal pattern may include a work-function metal that controls a threshold voltage of a transistor. A thickness and composition of the first metal pattern may be adjusted to achieve a desired threshold voltage of a transistor. For example, the first, second, and third inner electrodes PO1, PO2, and PO3 of the gate electrode GE may be formed of the first metal pattern or the work-function metal.

The first metal pattern may include a metal nitride layer. For example, the first metal pattern may include nitrogen (N) and at least one metal selected from titanium (Ti), tantalum (Ta), aluminum (Al), tungsten (W), and molybdenum (Mo). In addition, the first metal pattern may further include carbon (C). The first metal pattern may include a plurality of stacked work-function metal layers.

The second metal pattern may include metal with a resistance that is less than that of the first metal pattern. For example, the second metal pattern may include at least one metal selected from tungsten (W), aluminum (Al), titanium (Ti), and tantalum (Ta). For example, the outer electrode PO4 of the gate electrode GE may include a first metal pattern and a second metal pattern on the first metal pattern.

A pair of gate spacers GS may be disposed on opposite sidewalls of the outer electrode PO4 included in the gate electrode GE. The gate spacers GS may extend in the first direction D1 along the gate electrode GE. The gate spacers GS may have top surfaces higher than that of the gate electrode GE.

In one or more embodiments, the gate spacers GS may include at least one selected from SiCN, SiCON, and SiN. In one or more embodiments, the gate spacers GS may include a multiple layer formed of at least two selected from SiCN, SiCON, and SiN. In one or more embodiments, the gate spacer GS may include a silicon-containing dielectric material. The gate spacer GS may act as an etch stop layer when forming active contacts AC which will be described below. The gate spacer GS may cause a self-alignment formation of the active contacts AC.

A gate capping pattern GP may be provided on the gate electrode GE. The gate capping pattern GP may extend in the first direction D1 along the gate electrode GE. The gate capping pattern GP may include a material having an etch selectivity with respect to a first interlayer dielectric layer 120 which will be described below. For example, the gate capping pattern GP may include at least one selected from SiON, SiCN, SiCON, and SiN.

A gate dielectric layer GI may be interposed between the gate electrode GE and the channel pattern CH. The gate dielectric layer GI may cover a top surface, a bottom surface, and opposite sidewalls of each of the first, second, and third semiconductor patterns SP1, SP2, and SP3.

The gate dielectric layer GI may include one or more of a silicon oxide layer, a silicon oxynitride layer, and a high-k dielectric layer. For example, the gate dielectric layer GI may have a structure in which a silicon oxide layer and a high-k dielectric layer are stacked. The high-k dielectric layer may include a high-k dielectric material with dielectric constant that is greater than that of a silicon oxide layer. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

Alternatively, a semiconductor device according to one or more embodiments may include a negative capacitance FET (NCFET) that uses a negative capacitor. For example, the gate dielectric layer GI may include a ferroelectric material layer that exhibits ferroelectric properties and a paraelectric material layer that exhibits paraelectric properties.

The ferroelectric material layer may have a negative capacitance, and the paraelectric material layer may have a positive capacitance. For example, when two or more capacitors are connected in series, and when each capacitor has a positive capacitance, an overall capacitance may be reduced to be less than the capacitance of each capacitor. In contrast, when at least one of two or more capacitors connected in series has a negative capacitance, an overall capacitance may have a positive value that is increased to be greater than an absolute value of the capacitance of each capacitor.

When the ferroelectric material layer having a negative capacitance is connected in series to the paraelectric material layer having a positive capacitance, there may be an increase in overall capacitance of the ferroelectric and paraelectric material layers that are connected in series. The increase in overall capacitance may be used to allow a transistor including the ferroelectric material layer to have a sub-threshold swing of less than about 60 mV/decade at room temperature.

The ferroelectric material layer may have ferroelectric properties. The ferroelectric material layer may include, for example, at least one of hafnium oxide, hafnium zirconium oxide, barium strontium titanium oxide, and lead zirconium titanium oxide. For example, the hafnium zirconium oxide may be a material in which hafnium oxide is doped with zirconium (Zr). In one or more embodiments, the hafnium zirconium oxide may be a compound of hafnium (Hf), zirconium (Zr), and oxygen (O).

The ferroelectric material layer may further include impurities doped therein. For example, the impurities may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of impurities included in the ferroelectric material layer may be changed depending on the ferroelectric material that is included in the ferroelectric material layer.

When the ferroelectric material layer includes hafnium oxide, the ferroelectric material layer may include at least one of impurities such as gadolinium (Gd), silicon (Si), zirconium (Zr), aluminum (Al), and yttrium (Y).

When the impurities are aluminum (Al), the ferroelectric material layer may include about 3 to 8 atomic percent aluminum. The ratio of impurities may refer to a ratio of aluminum to the sum of hafnium and aluminum.

When the impurities are silicon (Si), the ferroelectric material layer may include about 2 to about 10 atomic percent silicon. When the impurities are yttrium (Y), the ferroelectric material layer may include about 2 to about 10 atomic percent yttrium. When the impurities are gadolinium (Gd), the ferroelectric material layer may include about 1 to about 7 atomic percent gadolinium. When the impurities are zirconium (Zr), the ferroelectric material layer may include about 50 to 80 atomic percent zirconium.

The paraelectric material layer may have paraelectric properties. The paraelectric material layer may include, for example, at least one of silicon oxide and high-k metal oxide. The metal oxide included in the paraelectric material layer may include, for example, at least one of hafnium oxide, zirconium oxide, and aluminum oxide, but embodiments are not limited thereto.

The ferroelectric and paraelectric material layers may include the same material. The ferroelectric material layer may have ferroelectric properties, but the paraelectric material layer may not have ferroelectric properties. For example, when the ferroelectric material layer and the paraelectric material layer include hafnium oxide, the hafnium oxide included in the ferroelectric material layer may have a crystal structure different from that of the hafnium oxide included in the paraelectric material layer.

The ferroelectric material layer may have a thickness having ferroelectric properties. The thickness of the ferroelectric material layer may range, for example, from about 0.5 nm to about 10 nm, but embodiments are not limited thereto. Because ferroelectric materials have a critical thickness that exhibits ferroelectric properties, the thickness of the ferroelectric material layer may depend on ferroelectric material.

For example, the gate dielectric layer GI may include a single ferroelectric material layer. For another example, the gate dielectric layer GI may include a plurality of ferroelectric material layers that are spaced apart from each other. The gate dielectric layer GI may have a stack structure in which a plurality of ferroelectric material layers are alternately stacked with a plurality of paraelectric material layers.

The single height cell SHC may have a first boundary BD1 and a second boundary BD2 that are opposite to each other in the second direction D2. The first and second boundaries BD1 and BD2 may extend in the first direction D1. The single height cell SHC may have a third boundary BD3 and a fourth boundary BD4 that are opposite to each other in the first direction D1. The third and fourth boundaries BD3 and BD4 may extend in the second direction D2.

The single height cell SHC may be provided on its opposite sides with a pair of separation structures DB that are opposite to each other in the second direction D2. For example, the pair of separation structures DB may be correspondingly provided on the first and second boundaries BD1 and BD2 of the single height cell SHC. The separation structure DB may extend in the first direction D1 parallel to the gate electrodes GE. A pitch between the separation structure DB and its adjacent gate electrode GE may be the same as the first pitch.

The separation structure DB may penetrate a first contact dielectric layer 111 and a second contact dielectric layer 121, and may extend into the active patterns AP. The separation structure DB may penetrate an upper portion of each of the active patterns AP. The separation structure DB may electrically separate an active region of the single height cell SHC from an active region of an adjacent another cell.

Active contacts AC may be provided to penetrate the first contact dielectric layer 111 and the second contact dielectric layer 121 to come into electrical connection with the source/drain patterns SD. A pair of active contacts AC may be provided on opposite sides of the gate electrode GE. In a plan view, each of the active contacts AC may have a linear shape which extends in the first direction D1.

The active contact AC may be a self-aligned contact. For example, the gate capping pattern GP and the gate spacer GS may be used to form the active contacts AC in a self-alignment manner. For example, the active contacts AC may cover at least a portion of a sidewall of the gate spacer GS. The active contacts AC may partially cover a top surface of the gate capping pattern GP.

The active contact AC and the source/drain pattern SD may be provided therebetween with a metal-semiconductor compound layer SC, for example, a silicide layer. The active contact AC may be electrically connected through the metal-semiconductor compound layer SC to the source/drain pattern SD. For example, the metal-semiconductor compound layer SC may include at least one selected from titanium silicide, tantalum silicide, tungsten silicide, nickel silicide, and cobalt silicide.

Gate contacts GC may be provided to penetrate the second contact dielectric layer 121 and the gate capping pattern GP to come into electrical connection with the gate electrodes GE. In a plan view, the gate contacts GC may be disposed to correspondingly overlap the first active region AR1 and the second active region AR2.

In one or more embodiments, the active contact AC may have an upper portion adjacent to the gate contact GC, and the upper portion of the active contact AC may be filled with an upper dielectric pattern UIP. A bottom surface of the upper dielectric pattern UIP may be lower than that of the gate contact GC. For example, the upper dielectric pattern UIP may cause the active contact AC adjacent to the gate contact GC to have a top surface lower than the bottom surface of the gate contact GC. Therefore, a short-circuit resulting from contact between the gate contact GC and its adjacent active contact AC may be prevented.

The active contact AC may include a conductive pattern FM and a barrier pattern BM that surrounds the conductive pattern FM. The gate contact GC may include a conductive pattern FM and a barrier pattern BM that surrounds the conductive pattern FM. For example, the conductive pattern FM may include at least one metal of aluminum, copper, tungsten, molybdenum, and cobalt. The barrier pattern BM may cover sidewalls and a bottom surface of the conductive pattern FM. The barrier pattern BM may include a metal layer and/or a metal nitride layer. The metal layer may include at least one selected from titanium, tantalum, tungsten, nickel, cobalt, and platinum. The metal nitride layer may include at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PtN) layer.

A wiring structure MST may be disposed. The wiring structure MST may be similar to the wiring structure MST described with reference to FIGS. 1 to 3.

The wiring structure MST may include an interlayer dielectric layer 1300. The interlayer dielectric layer 1300 may include a via dielectric layer 1301 and a wiring dielectric layer 1302 on the via dielectric layer 1301. The via dielectric layer 1301 may include a dielectric material. The wiring dielectric layer 1302 may include a dielectric material.

A first conductive wiring layer M1 may be provided. For example, the first conductive wiring layer M1 may include a first active line M1_I1 and a first gate line M1_I2. The wiring lines M1_I1 and M1_I2 of the first conductive wiring layer M1 may extend in parallel along the second direction D2.

The first conductive wiring layer M1 may further include a first active via VI11 and a first gate via VI12. The first active via VI11 and the first gate via VI12 may be respectively provided beneath the first active line M1_I1 and the first gate line M1_I2 of the first conductive wiring layer M1. The active contact AC and the first active line M1_I1 may be electrically connected to each other through the first active via VI11. The gate contact GC and the first gate line M1_I2 may be electrically connected to each other through the first gate via VI12.

The wiring lines M1_M1 and M1_I2 and their underlying vias VI11 and VI12 of the first conductive wiring layer M1 may be formed by independent processes of each other. For example, the wiring line M1_I1 and M1_I2 of the first wiring layer M1 may each be formed by a single damascene process. A sub-20 nm process may be employed to fabricate a semiconductor device according to the present embodiment.

A second conductive wiring layer M2 may be provided in the first conductive wiring layer M1. The second conductive wiring layer M2 may include a second active via VI21, a second gate via VI22, a second active line M2_I1, and a second gate line M2_I2. The second active via VI21, the second gate via VI22, the second active line M2_I1, and the second gate line M2_I2 may be respectively the same as the first active via VI11, the first gate via VI12, the first active line M1_I1, and the first gate line M1_I2.

The wiring structure MST may include a plurality of wiring layers that are stacked vertically (e.g., in the third direction D3) from the first conductive wiring layer M1 to an uppermost wiring layer MT. Below a wiring layer that corresponds to a bridge wiring layer Mn described with reference to FIGS. 1 to 3 among wiring layers of the wiring structure MST, the first conductive wiring layer M1 may be stacked thereon with a second conductive wiring layer M2, a third conductive wiring layer M3, . . . , and an (n−1)^{th} conductive wiring layer Mn−1.

A bridge wiring layer Mn may be disposed on the (n−1)^{th} conductive wiring layer Mn−1, and an (n+1)^{th} conductive wiring layer Mn+1 may be disposed on the bridge wiring layer Mn. The bridge wiring layer Mn may include an n^{th} active via VIn1, an n^{th} gate via VIn2, and an n^{th} line Mn_I or a connection line LMS.

The (n+1)^{th} conductive wiring layer Mn+1 may include an (n+1)^{th} active via VIn+11, an (n+1)^{th} gate via VIn+12, an (n+1)^{th} active line Mn+1_I1, and an (n+1)^{th} gate line Mn+1_I2.

The wiring lines of the conductive wiring layers M1, M2, . . . , Mn−1, Mn+1, . . . , and MT may include identical or different conductive materials. For example, the wiring lines of the conductive wiring layers M1, M2, . . . , Mn−1, Mn+1, . . . , and MT may include at least one metallic material selected from aluminum, copper, tungsten, molybdenum, ruthenium, and cobalt.

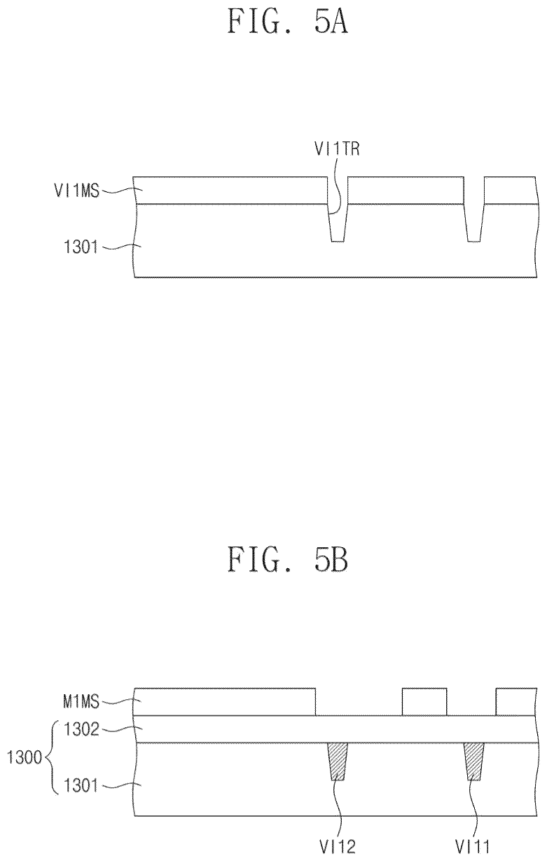

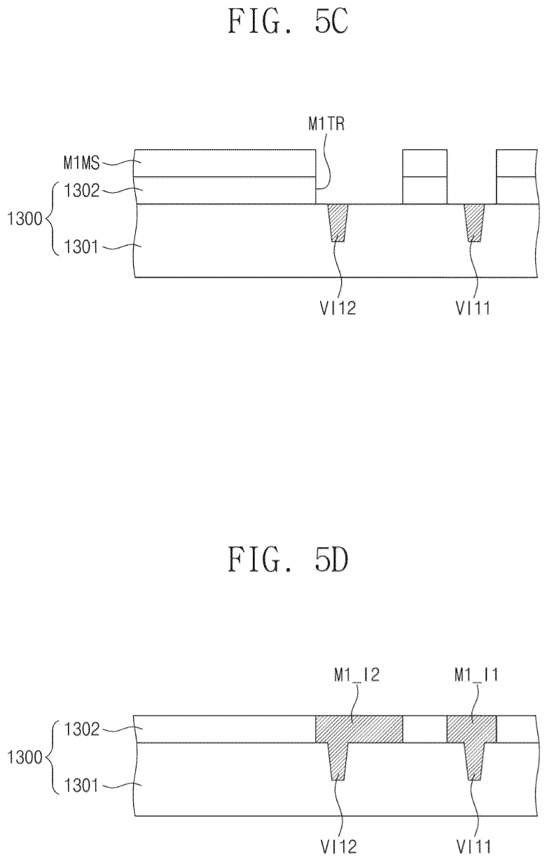

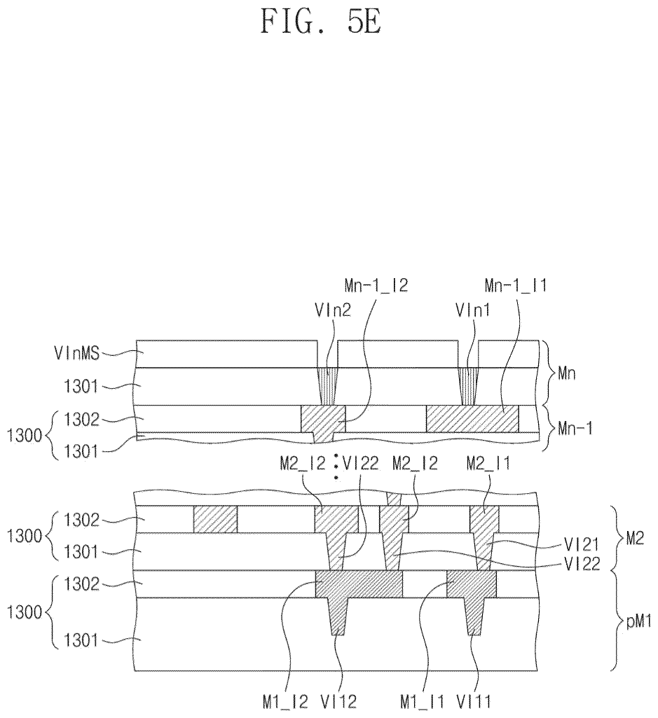

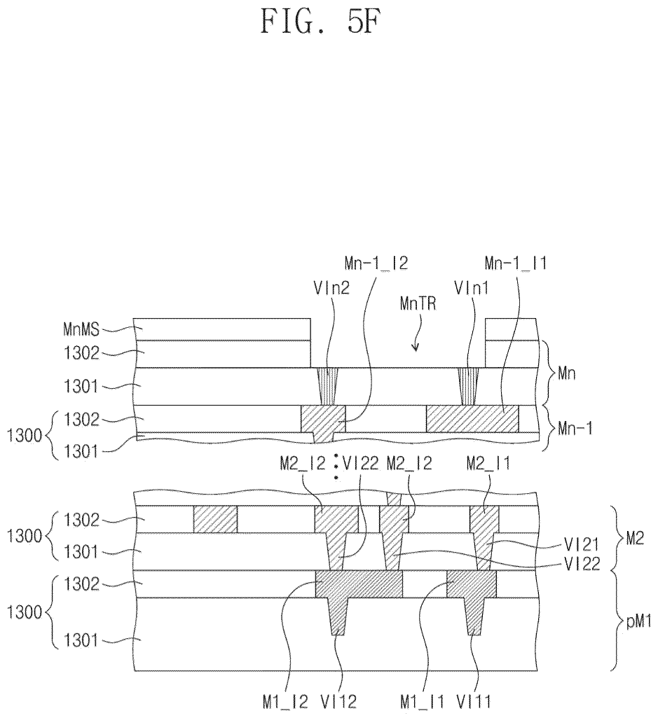

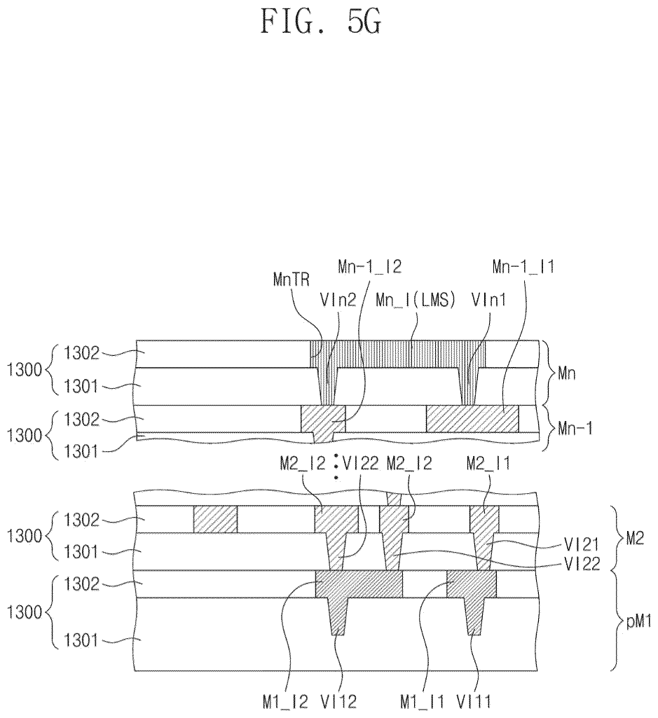

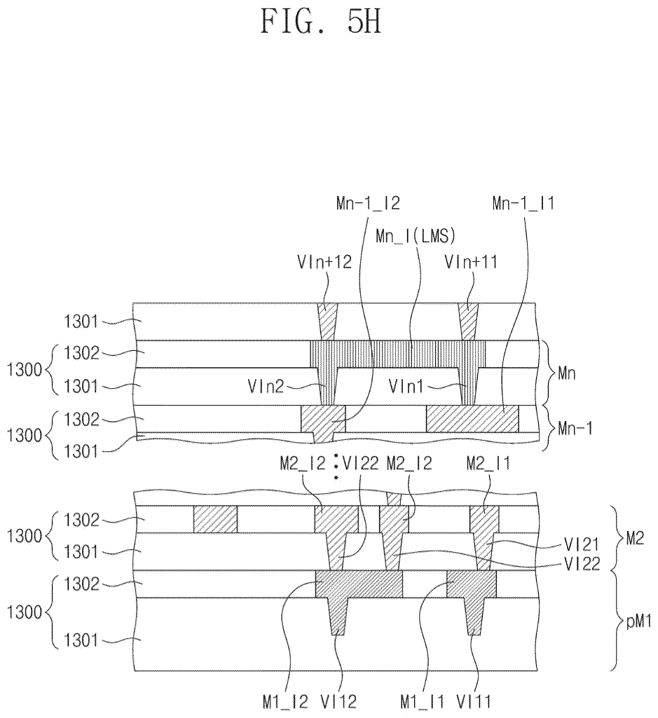

FIGS. 5A to 5H are cross-sectional views illustrating a method of fabricating a semiconductor device according to one or more embodiments. For example, FIGS. 5A to 5H may correspond to a method of fabricating the wiring structure MST according to one or more embodiments.

Referring to FIG. 5A, a via dielectric layer 1301 may be provided. A first via mask VI1MS may be provided on the via dielectric layer 1301. The first via mask VI1MS may be used to form a first via trench VI1TR on the via dielectric layer 1301. The first via trench VI1TR may have, for example, an irregular width.

Referring to FIG. 5B, a semi-damascene process and an etching process may be performed on the first via trench VI1TR to form a first active via VI11 and a first gate via VI12. The first active via VI11 and the first gate via VI12 may include the same conductive material. After the formation of the first active via VI11 and the first gate via VI12, the first via mask VI1MS may be removed, and a wiring dielectric layer 1302 may be formed on the via dielectric layer 1301. Afterwards, a first wiring mask MIMS may be formed on the via dielectric layer 1301. The first wiring mask M1MS may have mask patterns spaced apart from each other.

Referring to FIG. 5C, the first wiring mask M1MS may be used to form a first wiring trench M1TR on the wiring dielectric layer 1302. The first wiring trench M1TR may have, for example, a substantially constant width.

Referring to FIG. 5D, the first wiring trench M1TR may be filled with a conductive material. Thus, a first active line M1_I1 and a first gate line M1_I2 may be formed. After the formation of the first active line M1_I1 and the first gate line M1_I2, the first wiring mask M1MS may be removed.

Referring to FIG. 5E, the process described up to the formation of an (n−1)^{th} conductive wiring layer Mn−1 beneath a bridge wiring layer Mn may be repeatedly performed. As described with reference to FIGS. 5A and 5B, an n^{th} via mask VInMS may be used to form an n^{th} active via VIn1, and an n^{th} gate via VIn2 may be formed on the via dielectric layer 1301 of the bridge wiring layer Mn.

Referring to FIGS. 5F and 5G, a wiring dielectric layer 1302 may be formed on the via dielectric layer 1301, and an n^{th} wiring mask MnMS may be formed on the wiring dielectric layer 1302. The n^{th} wiring mask MnMS may be used to form a trench on the wiring dielectric layer 1302. The n^{th} wiring mask MnMS may be used to form on the wiring dielectric layer 1302 a bridge trench MnTR which exposes top surfaces of all of the n^{th} active via VIn1 and the n^{th} gate via VIn2.

The bridge trench MnTR may be filled with a conductive material. Thus, a connection line Mn_I (LMS) may be formed. The connection line Mn_I (LMS) may be formed to cover the exposed top surfaces of all of the n^{th} active via VIn1 and the n^{th} gate via VIn2. The bridge wiring layer Mn may be eventually formed.

Referring to FIG. 5H, a process similar to that of FIGS. 5A and 5B may be employed to form an (n+1)^{th} active via VIn+11 and an (n+1)^{th} gate via VIn+12 on the bridge wiring layer Mn. Thereafter, a process of FIGS. 5C to 5E may be repeated to form a wiring structure MST.

A three-dimensional field effect transistor (FET) according to one or more embodiments may have a bridge wiring layer including a connection line. Thus, an imbalance of charges induced to gates and/or source/drain patterns during fabrication process may be solved and a yield of a semiconductor device may be improved.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
a substrate;
a source/drain pattern on the substrate;
a gate structure on the substrate;
an active contact connected to the source/drain pattern;
a gate contact connected to the gate structure; and
a wiring structure on the active contact,
wherein the wiring structure comprises a bridge wiring layer and a plurality of conductive wiring layers,
wherein the bridge wiring layer comprises:
an active via connected to the active contact; and
a gate via connected to the gate contact,
wherein each conductive wiring layer of the plurality of conductive wiring layers comprises:
an active via connected to the active contact;
a gate via connected to the gate contact;
an active line on the active via of the respective conductive wiring layer; and
a gate line on the gate via of the respective conductive wiring layer, and
wherein the bridge wiring layer comprises a connection line connected to the active via of the bridge wiring layer and the gate via of the bridge wiring layer.

2. The semiconductor device of claim 1, wherein the connection line overlaps the active via of the bridge wiring layer and the gate via of the bridge wiring layer.

3. The semiconductor device of claim 1, wherein a width of the connection line is greater than a width of the active line of each conductive wiring layer of the plurality of conductive wiring layers.

4. The semiconductor device of claim 1, wherein at least two conductive wiring layers of the plurality of conductive wiring layers are vertically below the bridge wiring layer.

5. The semiconductor device of claim 1, wherein the connection line comprises copper.

6. The semiconductor device of claim 1, wherein the active line and the gate line of at least one conductive wiring layer of the plurality of conductive wiring layers are spaced apart from each other.

7. The semiconductor device of claim 1, wherein
an active via and a gate via of an uppermost conductive wiring layer of the plurality of conductive wiring layers are connected to an uppermost line.

8. The semiconductor device of claim 1, wherein the gate structure comprises:
a gate electrode comprising a conductive material;
a gate dielectric layer contacting the gate electrode; and
a gate spacer contacting the gate dielectric layer.

9. A semiconductor device comprising:
a substrate;
a source/drain pattern on the substrate;
a gate structure on the substrate;
an active contact connected to the source/drain pattern;
a gate contact connected to the gate structure; and
a wiring structure on the active contact,
wherein the wiring structure comprises a plurality of wiring layers that are vertically stacked,
wherein the plurality of wiring layers comprise:
a first conductive wiring layer contacting the active contact and the gate contact; and
a bridge wiring layer,
wherein the bridge wiring layer comprises:
an active via connected to the active contact; and
a gate via connected to the gate contact,
wherein the first conductive wiring layer comprises:
an active via connected to the active contact;
a gate via connected to the gate contact;
an active line contacting the active via of the first conductive wiring layer; and
a gate line spaced apart from the active line and on the gate via of the first conductive wiring layer, and
wherein the bridge wiring layer comprises a connection line contacting the active via of the bridge wiring layer and the gate via of the bridge wiring layer.

10. The semiconductor device of claim 9, wherein the plurality of wiring layers further comprise at least two wiring layers between the bridge wiring layer and the first conductive wiring layer.

11. The semiconductor device of claim 9, wherein the connection line vertically overlaps at least two gate structures.

12. The semiconductor device of claim 9, wherein a width of the connection line is greater than a width of the active line.

13. The semiconductor device of claim 9, wherein an active via and a gate via of an uppermost wiring layer of the plurality of wiring layers are connected to an uppermost line.

14. The semiconductor device of claim 13, wherein a width of the uppermost line is greater than a width of the active line.

15. The semiconductor device of claim 13, wherein the bridge wiring layer is between the uppermost wiring layer and the first conductive wiring layer, and
wherein the plurality of wiring layers further comprise at least one wiring layer between the uppermost wiring layer and the bridge wiring layer.

16. The semiconductor device of claim 9, wherein the active contact comprises:
a conductive pattern; and
a barrier pattern at least partially surrounding the conductive pattern, and
wherein the barrier pattern comprises a metal layer or a metal nitride layer.

17. The semiconductor device of claim 9, wherein the connection line vertically overlaps at least two vias.

18. A semiconductor device, comprising:
a substrate comprising an active pattern;
a channel pattern on the active pattern, wherein the channel pattern comprises a plurality of semiconductor patterns that are vertically stacked and spaced apart from each other;
a gate electrode on the plurality of semiconductor patterns;
a source/drain pattern on the active pattern;
a gate dielectric layer between the gate electrode and semiconductor patterns that are adjacent to each other;
a gate contact connected to the gate electrode;
an active contact connected to the source/drain pattern; and
a wiring structure on the active contact,
wherein the wiring structure comprises a bridge wiring layer and a plurality of conductive wiring layers,
wherein the bridge wiring layer comprises:
an active via connected to the active contact; and
a gate via connected to the gate contact,
wherein each conductive wiring layer of the plurality of conductive wiring layers comprises:
an active via connected to the active contact;
a gate via connected to the gate contact;
an active line on the active via of the respective conductive wiring layer; and
a gate line on the gate via of the respective conductive wiring layer, and
wherein the bridge wiring layer comprises a connection line connected to the active via of the bridge wiring layer and the gate via of the bridge wiring layer.

19. The semiconductor device of claim 18, wherein the connection line comprises aluminum, copper, tungsten, molybdenum, or cobalt.

20. The semiconductor device of claim 18, wherein a width of the connection line is greater than a width of the active line.
